(19) United States
(12) Patent Application Publication
(10) Pub. No.: US 2024/0354480 A1
(43) Pub. Date: Oct. 24, 2024

(54) Programmable Logic Circuits Using Lookup Tables (LUTs) Augmented with Configurable Logic Gates

(71) Applicants: Jeffrey Chromczak, Toronto (CA); Bee Yee Ng, Bayan Lepas (MY); Ilya Ganusov, San Jose, CA (US); Grace Zgheib, San Jose, CA (US)

(72) Inventors: Jeffrey Chromczak, Toronto (CA); Bee Yee Ng, Bayan Lepas (MY); Ilya Ganusov, San Jose, CA (US); Grace Zgheib, San Jose, CA (US)

(21) Appl. No.: 18/756,645

(22) Filed: Jun. 27, 2024

(51) Int. Cl. G06F 30/347

(52) U.S. Cl. CPC G06F 30/347

(57) ABSTRACT

To increase logic density at relatively low silicon area and power cost and limiting the adverse impacts on routability and placement flexibility, an enhanced programmable logic architecture may be implemented with a hybrid architecture including a combination of the configurable gate-based logic and lookup tables (LUTs) (and/or other heterogeneous logic resources). The hybrid combination of heterogeneous logic resources may share one or more interconnects and inputs, such that the various logic resources may be cascaded rather than mutually exclusive. Sharing of the interconnect may be beneficial as the interconnect may use the majority of the area, power, and delay on the FPGA, more than the logic itself. Accordingly, the shared interconnects may reduce die area, power consumption, and delay on the FPGA. The configurable gate-based logic may include Configurable NOR-Inverts (CNIs). The CNIs may share inputs with existing LUTs or may use LUTs outputs as OR-Invert inputs.

### BACKGROUND

The present disclosure relates generally to programmable logic devices (PLDs), such as field programmable gate arrays (FPGAs). More particular, the present disclosure relates to increasing logic density in FPGAs using configurable logic gates.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Programmable logic devices, a class of integrated circuits, may be programmed to perform a wide variety of operations. Some FPGAs include basic building blocks referred to as adaptive logic modules (ALMs) and/or any other appropriate logic element. ALMs are programmable logic resources that provide flexibility and reconfigurability for implementing various programmable logic functions. Increasing the capability of adaptive logic elements such as ALMs may be advantageous as a more capable ALM may enable implementation of a greater number of independent functions on an FPGA and may enable wider functions (e.g., functions with a greater number of input pins). A larger effective capacity may be achieved by increasing the ALM density on an FPGA. Greater ALM density may improve overall performance, as enhancing the ability of the FPGA to support wider functions may reduce critical path depth on the FPGA, which may improve data processing and reduce delay. However, increasing ALM density may in some cases negatively impact routability and placement flexibility.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of the integrated circuit device of FIG. 1, in accordance with an embodiment of the present disclosure;

FIG. 3 is a block diagram of a balanced configurable NOR-invert (CNI) network topology that may be embedded in one or more LABs described in FIG. 2 or one or more ALMs within the one or more LABs, in accordance with an embodiment of the present disclosure;

FIG. 4 is a block diagram of an unbalanced CNI network topology that may be embedded in one or more LABs described in FIG. 2 or one or more ALMs within the one or more LABs, in accordance with an embodiment of the present disclosure;

FIG. 5 is a block diagram of a CNI network topology including input inverters that may be embedded in one or more LABs described in FIG. 2 or one or more ALMs within the one or more LABs, in accordance with an embodiment of the present disclosure;

FIG. 6 is a block diagram of hybrid logic circuitry including a combination of LUTs and CNIs that may be embedded in one or more LABs described in FIG. 2 or one or more ALMs within the one or more LABs, in accordance with an embodiment of the present disclosure;

FIG. 7 is a block diagram illustrating the hybrid logic circuitry described with respect to FIG. 6 that is integrated at LAB-level, sharing input interconnects with ALMs disposed within a LAB, in accordance with an embodiment of the present disclosure;

FIG. 8 is a block diagram illustrating the hybrid logic circuitry integrated at LAB-level, sharing output interconnects with ALMs disposed within a LAB, in accordance with an embodiment of the present disclosure;

FIG. 9 is a block diagram illustrating the hybrid logic circuitry integrated at LAB-level, sharing input and output interconnects with ALMs disposed within a LAB, in accordance with an embodiment of the present disclosure;

FIG. 10 is a block diagram illustrating the cascaded CNI network topology (e.g., the CNI network topology described with respect to FIG. 3) implemented within the LAB, in accordance with an embodiment of the present disclosure;

FIG. 11 is a schematic diagram of an enhanced hybrid logic circuitry (e.g., an ALM) including an additional two-input LUT (2LUT) and a CNI, in accordance with an embodiment of the present disclosure;

FIG. 12 is a block diagram of the hybrid logic circuitry described with respect to FIG. 11 implemented at ALM-level, in accordance with an embodiment of the present disclosure; and

FIG. 13 is a data processing system including the integrated circuit system described with respect to FIG. 2 on which the embodiments described with respect to FIGS. 3-12 may be implemented, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

Programmable logic devices such as FPGAs include basic building blocks referred to as adaptive logic modules (ALMs) or logic elements, which are programmable logic resources or logic circuits made up of programmable logic resources (e.g., logic gates) that provide flexibility and reconfigurability for implementing various programmable logic functions. Increasing the density of adaptive logic elements such as ALMs may be advantageous as greater density enables a greater number of independent functions on an FPGA and enables wider functions (e.g., functions with a greater number of input pins). Indeed, greater ALM density may improve overall performance, as enhancing the ability of the FPGA to support wider functions may reduce critical path depth of the FPGA, improving data processing and reducing delay.

However, in some cases, increasing ALM density may negatively impact routability and placement flexibility. Accordingly, there may be a desire for increasing the ALM density while limiting adverse impact on placement and routability. In some circumstances, greater logic density may be achievable by mixing heterogenous logic resources into a hybrid logic architecture. However, some hybrid logic architectures may lead to underutilization of each type of resource, as the function composition of any given design may not match the heterogeneous logic resource mixture provided by the hybrid logic architecture. In some hybrid logic architectures, each resource type may have a dedicated routing interface (e.g., interconnect), so an underutilization of logic resources may become costly as unused resources consume logic and routing area. As routing consumes the majority of FPGA die-area, this can quickly lead to a net increase in silicon area.

To increase logic density at relatively low silicon area and power cost and limiting the adverse impacts on routability and placement flexibility, an enhanced programmable logic architecture may be implemented with configurable gate-based logic or a hybrid architecture including a combination of the configurable gate-based logic and lookup tables (LUTs) (and/or other heterogeneous logic resources), wherein the hybrid combination of heterogenous logic resources share one or more interconnects and inputs, such that the various logic resources may be cascaded rather than mutually exclusive. Sharing of the interconnect may be beneficial as the interconnect may use the majority of the area, power, and delay on the FPGA, more than the logic itself. Accordingly, the shared interconnects may reduce die area, power consumption, and delay on the FPGA. The configurable gate-based logic may include Configurable NOR-Inverts (CNIs). The CNIs may share inputs with existing LUTs or may use LUTs outputs as OR-Invert inputs. While the configurable gate-based logic may be referred to herein as CNIs, it should be noted that any appropriate configurable resource element may be used, such as an AND-Inverter Cone (AIC).

The proposed hybrid logic architecture results in improved logic density of FPGAs (e.g., effective gates/mm² of silicon area) compared to other known techniques. The proposed hybrid logic architecture may also enable mapping of wider functions to a single logic stage, which may reduce power (as less routing is used) and may improve the performance of the user design (as logic depth may be reduced).

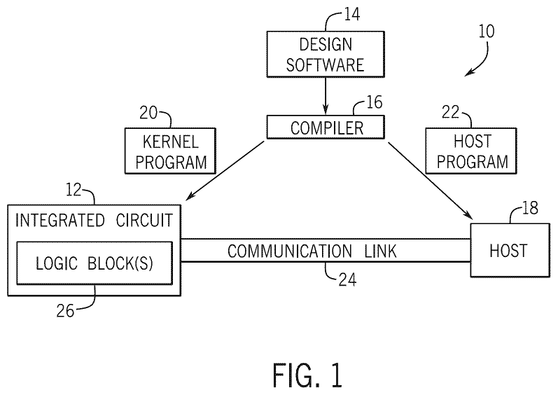

With the foregoing in mind, FIG. 1 illustrates a block diagram of a system 10 that may be used to implement the ALM hybrid logic architecture having LUTs augmented with configurable logic gates such as CNIs on an integrated circuit system 12 (e.g., a single monolithic integrated circuit or a multi-die system of integrated circuits). A designer may desire to implement the heterogeneous logic architecture on the integrated circuit system 12 (e.g., a programmable logic device such as a field-programmable gate array (FPGA) that includes programmable logic circuitry). The integrated circuit system 12 may include a single integrated circuit, multiple integrated circuits in a package, or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit system 12.

In a configuration mode of the integrated circuit system 12, a designer may use an electronic device (e.g., a computer) to implement high-level designs (e.g., a system user design) using design software 14, such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit system 12. The host 18 may receive a host program 22 that may control or be implemented by the kernel programs 20. To implement the host program 22, the host 18 may communicate instructions from the host program 22 to the integrated circuit system 12 via a communications link 24 that may include, for example, direct memory access (DMA) communications or peripheral component interconnect express (PCIe) communications. In some embodiments, the kernel programs 20 and the host 18 may configure programmable logic blocks 110 on the integrated circuit system 12. The programmable logic blocks 110 may include circuitry and/or other logic elements and may be configurable to implement a variety of functions in combination with digital signal processing (DSP) blocks 120.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

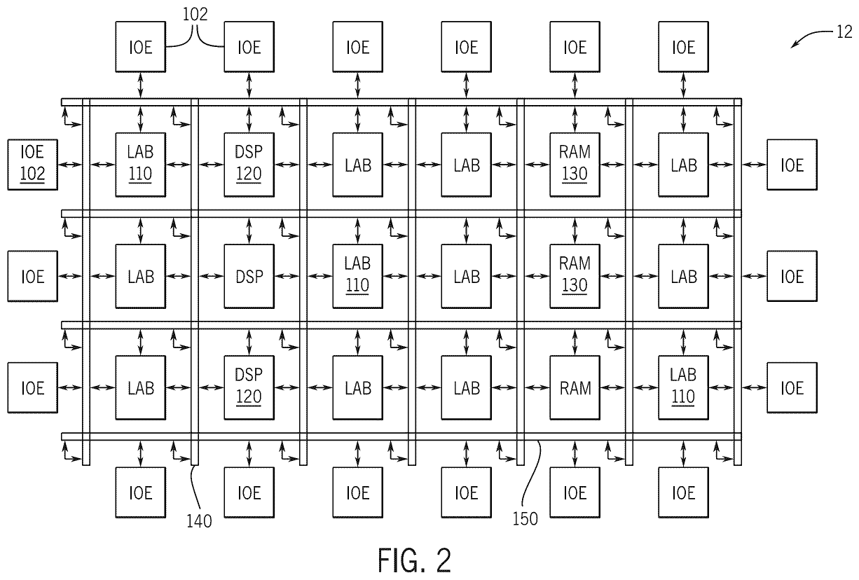

An illustrative embodiment of a programmable integrated circuit system 12 such as a programmable logic device (PLD) that may be configured to implement a circuit design is shown in FIG. 2. As shown in FIG. 2, the integrated circuit system 12 (e.g., a field-programmable gate array integrated circuit) may include a two-dimensional array of functional blocks, including programmable logic circuitry such as programmable logic blocks 110 (also referred to as logic array blocks (LABs) or configurable logic blocks (CLBs)) and other functional blocks, such as embedded digital signal processing (DSP) blocks 120 and embedded random-access memory (RAM) blocks 130, for example. Functional blocks such as LABs 110 may include smaller programmable regions (e.g., logic elements, configurable logic blocks, or ALMs) that receive input signals and perform custom functions on the input signals to produce output signals. LABs 110 may also be grouped into larger programmable regions sometimes referred to as logic sectors that are individually managed and configured by corresponding logic sector managers. The grouping of the programmable logic resources on the integrated circuit system 12 into logic sectors, logic array blocks, logic elements, or ALMs is merely illustrative. In general, the integrated circuit system 12 may include functional logic blocks of any suitable size and type, which may be organized in accordance with any suitable logic resource hierarchy.

Programmable logic on the integrated circuit system 12 may contain programmable memory elements. Memory elements may be loaded with configuration data (also called programming data or configuration bitstream) using input-output elements (IOEs) 102. Once loaded, the memory elements each provide a corresponding static control signal that controls the operation of an associated functional block (e.g., LABs 110, DSP 120, RAM 130, or input-output elements 102).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables (LUTs), logic arrays, AND, OR, NAND, and NOR logic gates, pass gates, configurable logic gates such as configurable NOR-inverts (CNIs), etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements. The integrated circuit system 12 may be configured to implement a custom circuit design. For example, the configuration RAM may be programmed such that LABs 110, DSP 120, and RAM 130, programmable interconnect circuitry (e.g., vertical channels 140 and horizontal channels 150), and the input-output elements 102 form the circuit design implementation.

In addition, the programmable logic device may have input-output elements (IOEs) 102 for driving signals off the integrated circuit system 12 and for receiving signals from other devices. Input-output elements 102 may include parallel input-output circuitry, serial data transceiver circuitry, differential receiver and transmitter circuitry, or other circuitry used to connect one integrated circuit to another integrated circuit.

The integrated circuit system 12 may also include programmable interconnect circuitry in the form of vertical routing channels 140 (e.g., interconnects formed along a vertical axis of the integrated circuit system 12) and horizontal routing channels 150 (e.g., interconnects formed along a horizontal axis of the integrated circuit system 12), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 2, are intended to be included within the scope of the present invention. For example, the routing topology may include wires that travel diagonally or that travel horizontally and vertically along different parts of their extent as well as wires that are perpendicular to the device plane in the case of three-dimensional integrated circuits, and the driver of a wire may be located at a different point than one end of a wire. The routing topology may include global wires that span substantially all of the integrated circuit system 12, fractional global wires such as wires that span part of the integrated circuit system 12, staggered wires of a particular length, smaller local wires, or any other suitable interconnection resource arrangement.

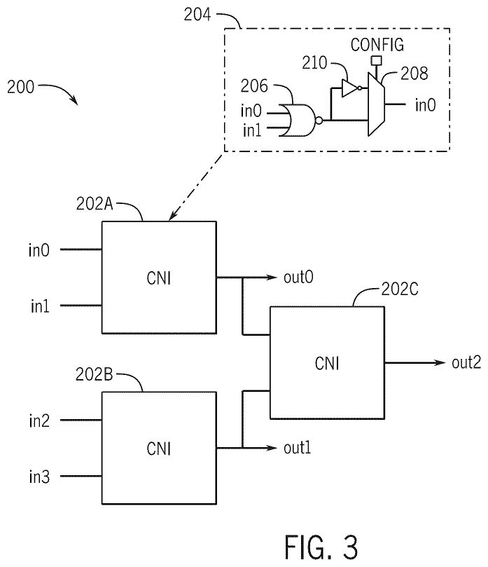

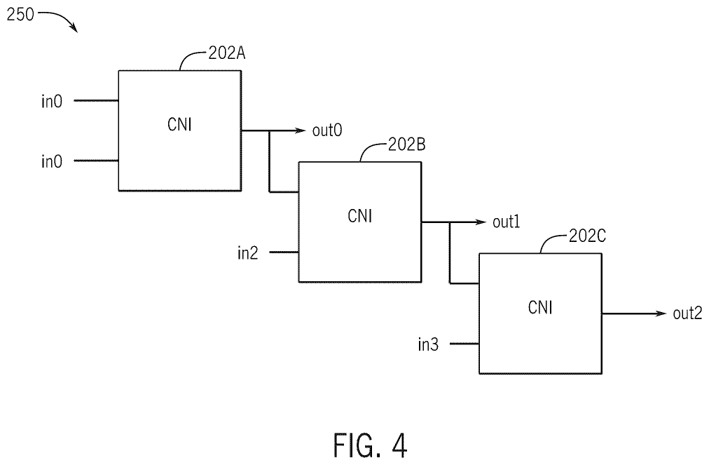

FIG. 3 is a block diagram of a CNI network topology 200, according to embodiments of the present disclosure. The CNI network topology 200 may include gate-based logic circuitry that may be implemented within (e.g., embedded in) programmable logic circuitry such as the LAB 110 or within a logic circuit (e.g., an ALM or other logic element, such as a basic logic element (BLE))) of a LAB 110 (or CLB). As used herein, LAB may refer to a CLB or any other group of logic blocks. The LAB 110 may include any suitable group of logic elements. Moreover, the components of the CNI network topology 200 may share the same routing circuitry (e.g., interconnects such as the vertical channels 140 and the horizontal channels 150). The CNI network topology 200 includes a CNI 202A including inputs in0 and in1 and output out0, a CNI 202B including inputs in2 and in3 and an output out1, and a cascaded CNI 202C that takes in the outputs out0 and out1 as inputs and has output out2. Collectively, the CNIs 202A, 202B, and 202C may be referred to herein as the CNIs 202. Each of the CNIs 202 may include the configurable gate-based logic 204. The configurable gate-based logic 204 includes a NOR gate 206 that may feed its output directly to a multiplexer 208 or to an inverter 210. Accordingly, the CNIs 202 may serve as either an OR gate or a NOR gate. The configurable inversion of the CNIs 202 also means that, when the CNIs 202 are cascaded together, the configurable output on stage N (e.g., the CNIs 202A and/or 202B) can serve as the configurable input on stage N+1 (e.g., the CNI 202C), which may enable a cascaded topology such as the CNI network topology 200 to perform OR, NOR, AND, and/or NAND functions. The CNI network topology 200 illustrates a balanced topology, but unbalanced topologies may be achievable as well, as will be illustrated in FIG. 4 below. Additionally, one or more of the CNIs 202 may be replaced by a LUT to expand the number of logic operations performable by the CNI network topology, as will be discussed in greater detail below. It should be noted that the CNIs 202 are not limited to NOR gates, and indeed may include any appropriate logic gate. It should also be noted that the cascaded structure of the CNI network topology 200 may include more CNIs 202 cascaded together, and that the CNI network topology 200 may only represent a portion of a larger CNI network.

FIG. 4 is a block diagram of an unbalanced CNI network topology 250, according to embodiments of the present disclosure. Similar to the CNI network topology 200, the unbalanced CNI network topology 250 may include a form of gate-based logic circuitry that may be implemented within (e.g., embedded in) a single logic element, such as a LAB 110, or within an ALM of a LAB 110. Moreover, the components of the unbalanced CNI network topology 250 may share the same routing circuitry (e.g., interconnects such as the vertical channels 140 and the horizontal channels 150). The unbalanced CNI network topology 250 includes the CNIs 202 as discussed above with respect to FIG. 3 above. In the unbalanced CNI network topology 250, the CNI 202A includes inputs in0 and in1 and output out0. The CNI 202B takes in as inputs the output of the CNI 202A out0 and/or the input in2, and outputs out1. The CNI 202C takes in as inputs the output of the CNI 202B out1 and/or the input in3, and outputs out2. Accordingly, the unbalanced CNI network topology 250 may operate multiple cascaded functions, such that the CNI 202B outputs a first-order cascaded function (e.g., as the input to the CNI 202B includes an output of the CNI 202A) and the CNI 202C outputs a second-order cascaded function (e.g., as the input to the CNI 202C includes a first-order cascaded function output by the CNI 202B). Additionally, one or more of the CNIs 202 may be replaced by a LUT to expand the number of logic operations performable by the unbalanced CNI network topology 250, as will be discussed in greater detail below. It may be appreciated that the unbalanced CNI network topology 250 is merely illustrative, and may include any number of CNIs 202 and/or any appropriate type of logic element cascaded together.

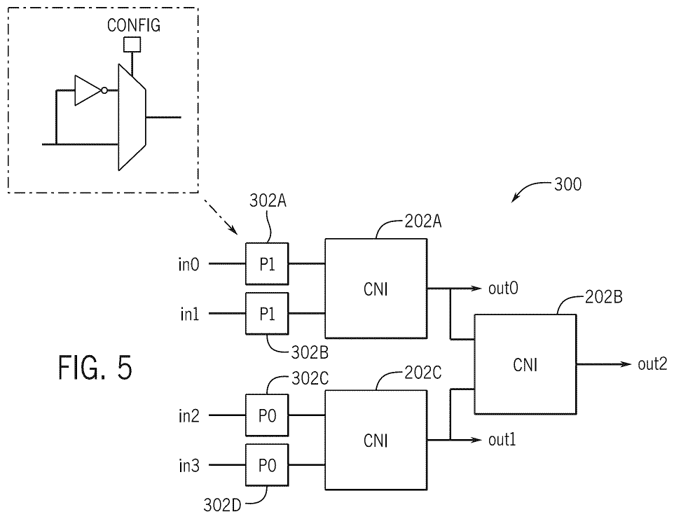

While the outputs of the CNIs 202 may be inverted due to the inverter 210 included in each respective CNI 202, in some cases, it may be beneficial for the inputs to the CNIs 202 to be inverted. FIG. 5 is a block diagram of a CNI network topology 300 including input inverters, according to embodiments of the present disclosure. Similar to the CNI network topology 200 and the unbalanced CNI network topology 250, the CNI network topology 300 may include gate-based logic circuitry that may be implemented within (e.g., embedded in) a single logic element, such as the LAB 110 or within an ALM of the LAB 110. Moreover, the components of the CNI network topology 300 may share the same routing circuitry (e.g., interconnects such as the vertical channels 140 and the horizontal channels 150). The CNI 202A includes an inverter 302A coupled at the input in0 and an inverter302B coupled at the input in1. The CNI 202B includes an inverter 302C coupled at the input in2 and an inverter 302D coupled at the input in3. Based on the architecture of the CNI network topology 300, the inputs and outputs of the CNIs 202 may be inverted. The input inverters 302 of the CNI network topology 300 may include programmable inverters such that the CNIs 202 may be programmable to invert or not invert. In this way, the input inverters 302 provide greater flexibility and functionality, as inverting the inputs of the logic gates may enable a greater number of independent functions. Additionally, in certain architectures, generating a certain signal (e.g., 0) may be less costly than generating another signal (e.g., 1). The inverters 302 may enable generating the less costly signal (e.g., 0) and inverting the signal (e.g., to a 1) whenever generating a 1 is appropriate. Moreover, certain ALM architectures may feature unused inputs. Unused inputs may be forced to a default value (e.g., a 0). However, in some situations, it may be disadvantageous to force 0s for the unused inputs (e.g., in logic architectures utilizing AND or NAND gates). The inverters 302 may prevent the default level from negatively impacting downstream functions by inverting the default level where appropriate.

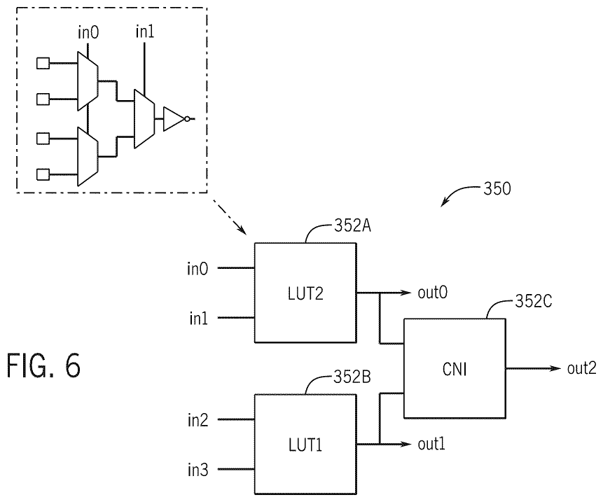

FIG. 6 is a block diagram of hybrid logic circuitry 350 including a combination of LUTs and CNIs, according to embodiments of the present disclosure. Similar to the CNI network topology 200, the unbalanced CNI network topology 250, and the CNI network topology 300, the hybrid logic circuitry 350 may include a combination of gate-based logic circuitry and LUTs that may be implemented within (e.g., embedded in) a single logic element, such as a LAB 110 or within an ALM of a LAB 110. Moreover, the components of the hybrid logic circuitry 350 may share the same routing circuitry (e.g., interconnects such as the vertical channels 140 and the horizontal channels 150). The hybrid logic circuitry 350 includes a LUT 352A including inputs in0 and in1 and an output out0, and includes a LUT 352B including inputs in2 and in3 and an output out1. Collectively, the LUT 352A and the LUT 352B may be referred to herein as the LUTs 352. The hybrid logic circuitry 350 includes the CNI 202, which takes in as inputs the output out0 of the LUT 352A and/or out1 of the LUT 352B and outputs out2. In this manner the hybrid logic circuitry 350 illustrates heterogeneous cascaded functions. While the CNIs 202 can implement functions such as AND, NAND, OR, and/or NOR, the LUTs 352 may provide universal functions. That is, the LUTs 352 may implement any appropriate logic function, such as AND, NAND, OR, NOR, XOR and/or XNOR, as well as providing route-throughs and constant generation, further improving the flexibility and functionality of the topologies described with respect to FIGS. 3-5. It should be noted that, while the hybrid logic circuitry 350 illustrates a balanced topology including two LUTS 352 and one CNI, any appropriate hybrid topology may be implemented. For example, the hybrid logic circuitry 350 may include an unbalanced topology as described with respect to FIG. 4. The hybrid logic circuitry 350 may include a balanced or unbalanced topology with inverted inputs, similar to the CNI network topology 300 described with respect to FIG. 5. The hybrid logic circuitry 350 may include multiple CNIs 202 coupled to a single LUT 352, multiple CNIs coupled to multiple LUTs 352, and so on.

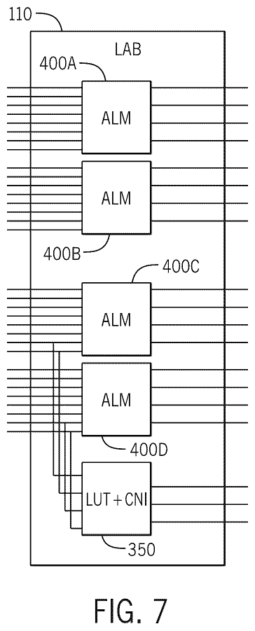

FIG. 7 is a block diagram illustrating the hybrid logic circuitry 350 integrated at LAB-level, sharing input interconnects with ALMs disposed within a LAB 110, according to embodiments of the present disclosure. The LAB 110 includes an ALM 400A, an ALM 400B, an ALM 400C, and an ALM 400D, which may collectively be referred to as the ALMs 400. The LAB 110 includes hybrid logic circuitry 350. The ALM 400C, the ALM 400D, and the hybrid logic circuitry 350 may share inputs between each other. The input sharing between the ALMs 400C and 400D and the hybrid logic circuitry 350 may be non-exclusive, such that the ALMs 400C and 400D may operate as they would without the hybrid logic circuitry 350, and the hybrid logic circuitry 350 is purely additive. The inputs of the hybrid logic circuitry 350 may include at least a portion of the inputs of the ALM 400C and/or at least a portion of the inputs of the ALM 400D. While only four ALMs 400 are shown in FIG. 7 and the figures described below, it should be noted that there may be any appropriate number of ALMs 400 in a LAB 110. For example, a LAB 110 may include 10 or more ALMs, 100 or more ALMs, 1,000 or more ALMs, and so on.

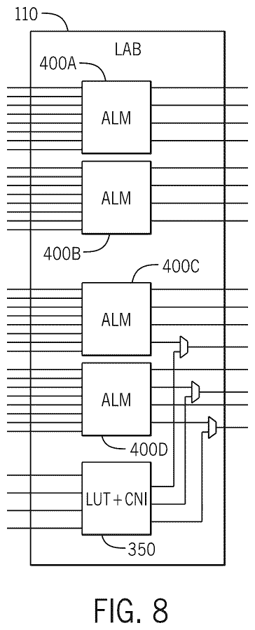

FIG. 8 is a block diagram illustrating the hybrid logic circuitry 350 integrated at LAB-level, sharing output interconnects with ALMs disposed within the LAB 110, according to embodiments of the present disclosure. As may be observed, the ALM 400C, the ALM 400D, and the hybrid logic circuitry 350 may share outputs between each other. The output sharing between the ALMS 400C and 400D and the hybrid logic circuitry 350 may be non-exclusive, such that the ALMs 400C and 400D may operate as they would without the hybrid logic circuitry 350, and the hybrid logic circuitry 350 is purely additive. The outputs of the hybrid logic circuitry 350 may include at least a portion of the outputs of the ALM 400C and/or at least a portion of the outputs of the ALM 400D.

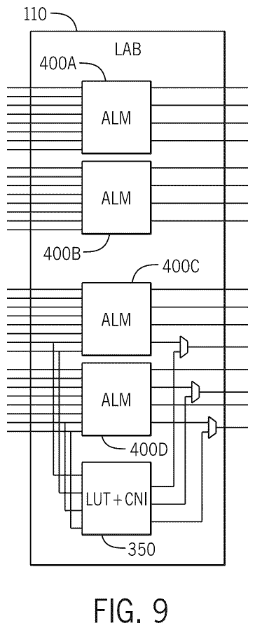

FIG. 9 is a block diagram illustrating the hybrid logic circuitry 350 integrated at LAB-level, sharing input and output interconnects with ALMs disposed within the LAB 110, according to embodiments of the present disclosure. As may be observed, the ALM 400C, the ALM 400D, and the hybrid logic circuitry 350 may share both inputs and outputs between each other. The input and output sharing between the ALMs 400C and 400D and the hybrid logic circuitry 350 may be non-exclusive, such that the ALMs 400C and 400D may operate as they would without the hybrid logic circuitry 350, and the hybrid logic circuitry 350 is purely additive. The inputs and outputs of the hybrid logic circuitry 350 may include at least a portion of the inputs and outputs of the ALM 400C and/or at least a portion of the inputs and outputs of the ALM 400D.

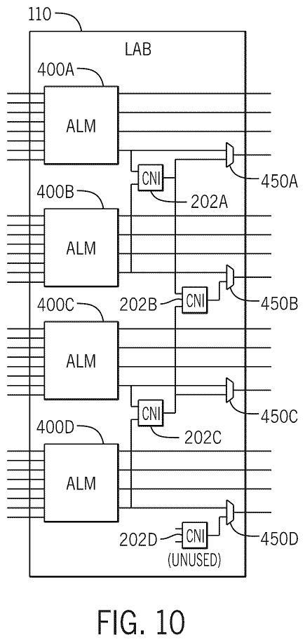

FIG. 10 is a block diagram illustrating the cascaded CNI network topology (e.g., the CNI network topology 200 described with respect to FIG. 3) implemented within the LAB 110, according to embodiments of the present disclosure. The CNI 202A may receive, as inputs, outputs of the ALMs 400A and 400B. The CNI 202A may output to the CNI 202B and/or a multiplexer 450A. The multiplexer 450A may output the output signal from the CNI 202A or a direct output from the ALM 400A. The multiplexer 450A may output to a register or to another LAB 110. The CNI 202C may receive, as inputs, outputs of the ALMs 400C and 400D. The CNI 202C may output to the CNI 202B and/or a multiplexer 450C. The multiplexer 450C may output the output signal from the CNI 202C or a direct output from the ALM 400C. The multiplexer 450C may output to a register or to another LAB 110. The CNI 202B may receive, as inputs, outputs of the CNIs 202A and 202C. The CNI 202B may output to a multiplexer 450B. The multiplexer 450B may output the output signal from the CNI 202B or a direct output from the ALM 400B. The multiplexer 450B may output to a register or to another LAB 110. The CNI 202D may be uncoupled from the ALMs 400 in the LAB 110. A multiplexer 450D may output the output signal directly from the ALM 400D.

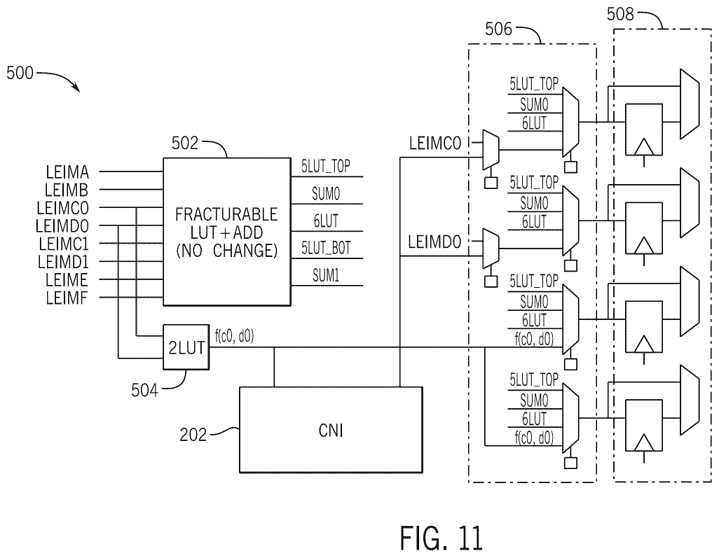

FIG. 11 is a schematic diagram of an enhanced hybrid logic circuitry (e.g., an ALM) including an additional two-input LUT (2LUT) and a CNI, according to embodiments of the present disclosure. The enhanced hybrid logic circuitry 500 includes a fracturable LUT 502 having multiple inputs, such as logic-element input multiplexer (LEIM) inputs. Fracturable LUTs are LUTs that may be “fractured” or separated into multiple smaller LUTs to provide a greater number of unique functions within an ALM. For example, a 6LUT may be fractured into two 3LUTs, three 2LUTs, two 5LUTs (e.g., with input sharing) and so on. While the LUT 502 is illustrated and described as a fracturable 6LUT having eight inputs, it should be noted that the LUT 502 may include a LUT of any appropriate size, such as a 5LUT, 4LUT, 3LUT, 2LUT, and so on. As the LUT 502 is a fracturable 6LUT, the LUT may function as two 3LUTs, three 2LUTs, two 5 LUTs (e.g., with input-sharing), and so on. Accordingly, the outputs of the LUT 502 may correspond to outputs from any function available in the LUT 502. For example, the outputs may include a 6LUT output, a 5LUT output, one or more 3LUT outputs, one or more 2LUT outputs, and so on.

Some ALMs may have unused or underutilized inputs, such as the LEIMC0 input and the LEIMD0 input. As the input routing of the ALM consumes the majority of the die area on a programmable logic device (e.g., an FPGA), the unused or underutilized input pins may be undesirable. To utilize these input pins and improve ALM performance, an additional LUT 504 (e.g., a 2LUT) may be implemented in the enhanced hybrid logic circuitry 500. While the additional LUT 504 is illustrated as a 2LUT, it should be noted that any appropriately sized LUT may be implemented as an additional LUT in the enhanced hybrid logic circuitry 500. For example, the additional LUT 504 may include a 3LUT, a 4LUT, and so on, depending on the die area available in the ALM, the number of pins available, and so on.

If coupled to inputs of the LUT 502, the additional LUT 504 may perform additional independent functions. Moreover, if coupled to unused inputs of the LUT 502, the independent functions provided by the additional LUT 504 may be purely additive. If coupled to outputs of the LUT 502, the additional LUT 504 may enable cascaded functions within the enhanced hybrid logic circuitry 500. The enhanced hybrid logic circuitry 500 may include gate-based logic circuitry, such as the CNI 202. The CNI 202 may be coupled to an output of the additional LUT 504 to provide greater flexibility and functionality, as described with respect to FIG. 6 above. It should be noted that the topologies described with respect to FIG. 3-6 may be implemented in the enhanced hybrid logic circuitry 500, such that one or more CNIs 202 and one or more additional LUTs 504 may be cascaded with each other in balanced or unbalanced topologies. Routing circuitry 506 and registers 508 may receive input signals from the inputs of the LUT 502, output signals from the outputs of the LUT 502, outputs from the additional LUT 504, outputs of the CNI 202, or any combination thereof.

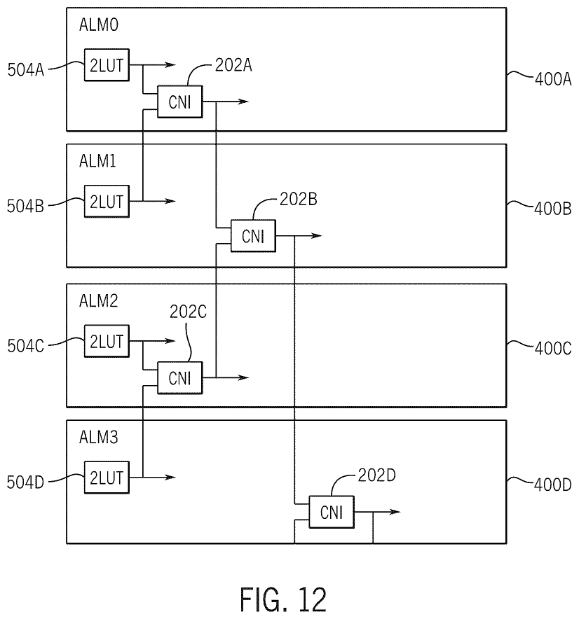

FIG. 12 is a block diagram of the hybrid logic circuitry described with respect to FIG. 11 implemented at ALM-level, according to embodiments of the present disclosure. ALMs 400A, 400B, 400C, and 400D may include additional LUTs 504 and cascaded CNIs 202. The ALM 400A includes an additional LUT 504A and a CNI 202A, the ALM 400B includes an additional LUT 504B and a CNI 202B, the ALM 400C includes an additional LUT 504C and a CNI 202C, and the ALM 400D includes an additional LUT 504D and a CNI 202D. The additional LUTs 504A, 504B, 504C, and 504D may be collectively referred to herein as the additional LUTs 504. While not shown, respective LUTs 502 may be disposed at the input of each respective additional LUT 504 as described with respect to the enhanced hybrid logic circuitry of FIG. 11.

The CNI 202A may receive, as inputs, respective outputs from the additional LUT 504A and the additional LUT 504B. The CNI 202A may output to an input of the CNI 202B. The CNI 202C may receive, as inputs, respective outputs from the additional LUTs 504C and 504D and output a signal to the input of the CNI 202B, such that a cascaded function is provided. The CNI 202B may perform additional logic operations on the signals received from the CNIs 202A and 202C, and output a signal to the CNI 202D to provide yet another stage of cascaded functionality. While only four ALMs 400 are shown in FIGS. 7-10 and 12, it should be noted that there may be any appropriate number of ALMs 400 in a LAB 110. For example, a LAB 110 may include 10 or more ALMs, 100 or more ALMs, 1,000 or more ALMs, and so on.

The proposed architectures described above may result in improved logic density of FPGAs (e.g., effective gates/mm² of silicon area) compared to other known techniques. The proposed architectures may also enable mapping of wider functions to a single logic stage, which may reduce power (as less routing is used) and may improve the performance of the user design (as logic depth may be reduced).

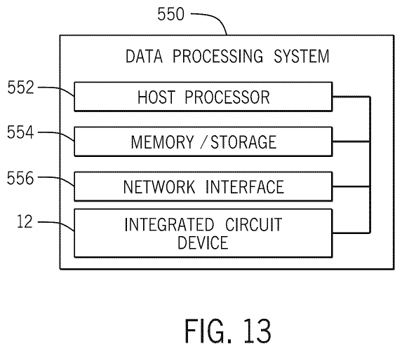

The processes discussed above may be carried out on the integrated circuit system 12, which may be a component included in a data processing system, such as a data processing system 550, shown in FIG. 13. The data processing system 550 may include the integrated circuit system 12 (e.g., a programmable logic device), a host processor 552, memory and/or storage circuitry 554, and a network interface 556. The data processing system 550 may include more or fewer components (e.g., electronic display, user interface structures, application specific integrated circuits (ASICs)). The host processor 552 may include any of the foregoing processors that may manage a data processing request for the data processing system 550 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 554 may include random access memory (RAM), read-only memory (ROM), one or more hard drives, flash memory, or the like. The memory and/or storage circuitry 554 may hold data to be processed by the data processing system 550. In some cases, the memory and/or storage circuitry 554 may also store configuration programs (e.g., bitstreams, mapping function) for programming the integrated circuit system 12. The network interface 556 may allow the data processing system 550 to communicate with other electronic devices. The data processing system 550 may include several different packages or may be contained within a single package on a single package substrate. For example, components of the data processing system 550 may be located on several different packages at one location (e.g., a data center) or multiple locations. For instance, components of the data processing system 550 may be located in separate geographic locations or areas, such as cities, states, or countries.

The data processing system 550 may be part of a data center that processes a variety of different requests. For instance, the data processing system 550 may receive a data processing request via the network interface 556 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. For example, the programmable routing bridge described herein may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### EXAMPLE EMBODIMENTS

EXAMPLE EMBODIMENT 1. Programmable logic circuitry comprising:
first logic circuitry comprising a first set of inputs;
second logic circuitry comprising a second set of inputs; and
third logic circuitry comprising:
   one or more lookup tables (LUTs) and one or more configurable NOR-inverts (CNIs); and
   a third set of inputs comprising at least a first portion of the first set of inputs, a second portion of the second set of inputs, or both.

EXAMPLE EMBODIMENT 2. The programmable logic circuitry of example embodiment 1, wherein the first logic circuitry comprises a first set of outputs.

EXAMPLE EMBODIMENT 3. The programmable logic circuitry of example embodiment 2, wherein the second logic circuitry comprises a second set of outputs.

EXAMPLE EMBODIMENT 4. The programmable logic circuitry of example embodiment 3, wherein the third logic circuitry comprises a third set of outputs comprising at least a first portion of the first set of outputs, a second portion of the second set of outputs, or both.

EXAMPLE EMBODIMENT 5. The programmable logic circuitry of example embodiment 1, wherein the first logic circuitry, the second logic circuitry, or both comprise adaptive logic modules (ALMs).

EXAMPLE EMBODIMENT 6. The programmable logic circuitry of example embodiment 1, wherein the third logic circuitry comprises:
a first LUT comprising a first input, a second input, and a first output;
a second LUT comprising a third input, a fourth input, and a second output; and
a CNI comprising a fifth input coupled to the first output of the first LUT, a sixth input coupled to the second output of the second LUT, and a third output.

EXAMPLE EMBODIMENT 7. The programmable logic circuitry of example embodiment 1, wherein the third logic circuitry comprises:
a first CNI comprising a first input, a second input, and a first output;
a second CNI comprising a third input, a fourth input, and a second output; and
a third CNI comprising a fifth input, a sixth input, and a third output.

EXAMPLE EMBODIMENT 8. The programmable logic circuitry of example embodiment 7, wherein the fifth input is coupled to the first output of the first CNI and the sixth input is coupled to the second output of the second CNI.

EXAMPLE EMBODIMENT 9. The programmable logic circuitry of example embodiment 7, wherein the third input of the second CNI is coupled to the first output of the first CNI.

EXAMPLE EMBODIMENT 10. The programmable logic circuitry of example embodiment 7, wherein the fifth input of the third CNI is coupled to the second output of the second CNI.

EXAMPLE EMBODIMENT 11. An integrated circuit comprising:
routing circuitry comprising one or more horizontal channels and one or more vertical channels; and
programmable logic circuitry comprising:
   first logic circuitry comprising a first output;
   second logic circuitry comprising a second output; and
   a first configurable NOR-inverter (CNI) comprising a first input coupled to the first output of the first logic circuitry and a second input coupled to the second output of the second logic circuitry.

EXAMPLE EMBODIMENT 12. The integrated circuit of example embodiment 11, wherein the programmable logic circuitry comprises a multiplexer comprising a third input coupled to the first output of first logic circuitry and a second input coupled to a third output of the first CNI.

EXAMPLE EMBODIMENT 13. The integrated circuit of example embodiment 11, wherein the programmable logic circuitry comprises:
third logic circuitry comprising a third output;
fourth logic circuitry comprising a fourth output; and
a second CNI configurable to receive the third output of the third logic circuitry and configurable to receive the fourth output of the fourth logic circuitry.

EXAMPLE EMBODIMENT 14. The integrated circuit of example embodiment 13, wherein the programmable logic circuitry comprises a third CNI configurable to receive a fifth output from the first CNI and a sixth output from the second CNI.

EXAMPLE EMBODIMENT 15. The integrated circuit of example embodiment 11, wherein the first logic circuitry, the second logic circuitry, or both comprise adaptive logic modules (ALMs).

EXAMPLE EMBODIMENT 16. The integrated circuit of example embodiment 11, wherein the first logic circuitry, the second logic circuitry, or both comprise:
a first lookup table (LUT);
a second LUT; and
a CNI.

EXAMPLE EMBODIMENT 17. Logic circuitry comprising:
a first lookup table (LUT) comprising a first input, a second input, and a first output;
a second LUT comprising a third input, a fourth input, and a second output; and
a configurable NOR-invert (CNI) comprising a fifth input coupled to the first output of the first LUT, a sixth input coupled to the second output of the second LUT, and a third output.

EXAMPLE EMBODIMENT 18. The logic circuitry of example embodiment 17, wherein the CNI comprises:
a NOR gate comprising a third output coupled to an inverter input and a multiplexer input of a multiplexer; and
wherein the multiplexer comprises a fourth output, the fourth output comprising the third output.

EXAMPLE EMBODIMENT 19. The logic circuitry of example embodiment 17, wherein the first input, the second input, the third input, the fourth input, or any combination thereof comprise a configurable inverter.

EXAMPLE EMBODIMENT 20. The logic circuitry of example embodiment 17, wherein the first LUT, the second LUT, and the CNI comprise shared interconnects.

What is claimed is:

1. Programmable logic circuitry comprising:
first logic circuitry comprising a first set of inputs;
second logic circuitry comprising a second set of inputs; and
third logic circuitry comprising:
one or more lookup tables (LUTs) and one or more configurable NOR-inverts (CNIs); and
a third set of inputs comprising at least a first portion of the first set of inputs, a second portion of the second set of inputs, or both.

2. The programmable logic circuitry of claim 1, wherein the first logic circuitry comprises a first set of outputs.

3. The programmable logic circuitry of claim 2, wherein the second logic circuitry comprises a second set of outputs.

4. The programmable logic circuitry of claim 3, wherein the third logic circuitry comprises a third set of outputs comprising at least a first portion of the first set of outputs, a second portion of the second set of outputs, or both.

5. The programmable logic circuitry of claim 1, wherein the first logic circuitry, the second logic circuitry, or both comprise adaptive logic modules (ALMs).

6. The programmable logic circuitry of claim 1, wherein the third logic circuitry comprises:
a first LUT comprising a first input, a second input, and a first output;
a second LUT comprising a third input, a fourth input, and a second output; and
a CNI comprising a fifth input coupled to the first output of the first LUT, a sixth input coupled to the second output of the second LUT, and a third output.

7. The programmable logic circuitry of claim 1, wherein the third logic circuitry comprises:
a first CNI comprising a first input, a second input, and a first output;
a second CNI comprising a third input, a fourth input, and a second output; and
a third CNI comprising a fifth input, a sixth input, and a third output.

8. The programmable logic circuitry of claim 7, wherein the fifth input is coupled to the first output of the first CNI and the sixth input is coupled to the second output of the second CNI.

9. The programmable logic circuitry of claim 7, wherein the third input of the second CNI is coupled to the first output of the first CNI.

10. The programmable logic circuitry of claim 7, wherein the fifth input of the third CNI is coupled to the second output of the second CNI.

11. An integrated circuit comprising:
routing circuitry comprising one or more horizontal channels and one or more vertical channels; and
programmable logic circuitry comprising:
first logic circuitry comprising a first output;
second logic circuitry comprising a second output; and
a first configurable NOR-inverter (CNI) comprising a first input coupled to the first output of the first logic circuitry and a second input coupled to the second output of the second logic circuitry.

12. The integrated circuit of claim 11, wherein the programmable logic circuitry comprises a multiplexer comprising a third input coupled to the first output of first logic circuitry and a second input coupled to a third output of the first CNI.

13. The integrated circuit of claim 11, wherein the programmable logic circuitry comprises:
third logic circuitry comprising a third output;
fourth logic circuitry comprising a fourth output; and
a second CNI configurable to receive the third output of the third logic circuitry and configurable to receive the fourth output of the fourth logic circuitry.

14. The integrated circuit of claim 13, wherein the programmable logic circuitry comprises a third CNI configurable to receive a fifth output from the first CNI and a sixth output from the second CNI.

15. The integrated circuit of claim 11, wherein the first logic circuitry, the second logic circuitry, or both comprise adaptive logic modules (ALMs).

16. The integrated circuit of claim 11, wherein the first logic circuitry, the second logic circuitry, or both comprise:
a first lookup table (LUT);
a second LUT; and
a CNI.

17. Logic circuitry comprising:
a first lookup table (LUT) comprising a first input, a second input, and a first output;
a second LUT comprising a third input, a fourth input, and a second output; and
a configurable NOR-invert (CNI) comprising a fifth input coupled to the first output of the first LUT, a sixth input coupled to the second output of the second LUT, and a third output.

18. The logic circuitry of claim 17, wherein the CNI comprises:
a NOR gate comprising a third output coupled to an inverter input and a multiplexer input of a multiplexer; and
wherein the multiplexer comprises a fourth output, the fourth output comprising the third output.

19. The logic circuitry of claim 17, wherein the first input, the second input, the third input, the fourth input, or any combination thereof comprise a configurable inverter.

20. The logic circuitry of claim 17, wherein the first LUT, the second LUT, and the CNI comprise shared interconnects.
